(19) United States
(12) Patent Application Publication
(10) Pub. No.: US 2024/0088212 A1
(43) Pub. Date: Mar. 14, 2024

(54) SEMICONDUCTOR DEVICE AND MANUFACTURING METHOD OF SEMICONDUCTOR DEVICE

(71) Applicant: DENSO CORPORATION, Kariya-city (JP)

(72) Inventors: MASAKAZU WATANABE, Kariya-city (JP); YASUHIRO HIRABAYASHI, Kariya-city (JP)

(21) Appl. No.: 18/517,243

(22) Filed: Nov. 22, 2023

Related U.S. Application Data
(63) Continuation of application No. PCT/JP2021/045864, filed on Dec. 13, 2021.

(30) Foreign Application Priority Data
Jul. 6, 2021 (JP) 2021-112201

(51) Int. Cl. H01L 29/06; H01L 29/16; H01L 29/66; H01L 29/78

(52) U.S. Cl. CPC H01L 29/0607; H01L 29/1608; H01L 29/66068; H01L 29/7811

(57) ABSTRACT

A semiconductor device includes a semiconductor layer having an element region and a termination region located around the element region. The termination region includes a first breakdown voltage holding structure disposed in a first depth range of the semiconductor layer, and a second breakdown voltage holding structure disposed in a second depth range different from the first depth range of the semiconductor layer and arranged so as to face the first breakdown voltage holding structure in a depth direction of the semiconductor layer. At least one of the first breakdown voltage holding structure or the second breakdown voltage holding structure includes a RESURF layer. An electric field intensity distribution of the first breakdown voltage holding structure and an electric field intensity distribution of the second breakdown voltage holding structure have an opposite relationship of height from an inner peripheral side toward an outer peripheral side of the termination region.

### CROSS REFERENCE TO RELATED APPLICATIONS

The present application is a continuation application of International Patent Application No. PCT/JP2021/045864 filed on Dec. 13, 2021, which designated the U.S. and claims the benefit of priority from Japanese Patent Application No. 2021-112201 filed on Jul. 6, 2021. The entire disclosures of all of the above applications are incorporated herein by reference.

### TECHNICAL FIELD

The present disclosure relates to a semiconductor device and a manufacturing method of a semiconductor device.

### BACKGROUND

There has been known a semiconductor device in which a plurality of p-type guard rings and a plurality of p-type diffusion regions are disposed in a termination region of a semiconductor layer.

### SUMMARY

According to one aspect of the present disclosure, a semiconductor device includes a semiconductor layer having an element region and a termination region located around the element region. The termination region includes a first breakdown voltage holding structure disposed in a first depth range of the semiconductor layer, and a second breakdown voltage holding structure disposed in a second depth range different from the first depth range of the semiconductor layer and arranged so as to face the first breakdown voltage holding structure in a depth direction of the semiconductor layer. At least one of the first breakdown voltage holding structure or the second breakdown voltage holding structure includes a reduced surface field (RESURF) layer. An electric field intensity distribution of the first breakdown voltage holding structure and an electric field intensity distribution of the second breakdown voltage holding structure have an opposite relationship of height from an inner peripheral side toward an outer peripheral side of the termination region.

According to another aspect of the present disclosure, a manufacturing method of a semiconductor device includes: forming a mask on a semiconductor layer, the mask having an opening ratio that changes along at least one direction parallel to an upper surface of the semiconductor layer; reflowing the mask to change a thickness of the mask along the at least one direction; and implanting impurity ions into the semiconductor layer through the mask after the reflowing to form a RESURF layer.

### BRIEF DESCRIPTION OF DRAWINGS

Objects, features and advantages of the present disclosure will become apparent from the following detailed description made with reference to the accompanying drawings. In the drawings:

FIG. 1 is a diagram schematically showing a plan view of a semiconductor device according to an embodiment;

FIG. 2 is a diagram schematically showing a cross-sectional view of a main part of the semiconductor device taken along line II-II in FIG. 1;

FIG. 3 is a diagram schematically showing a cross-sectional view of the main part in a process of manufacturing the semiconductor device shown in FIG. 1;

FIG. 4 is a diagram schematically showing a cross-sectional view of the main part in another process of manufacturing the semiconductor device shown in FIG. 1;

FIG. 5 is a diagram schematically showing a cross-sectional view of the main part in another process of manufacturing the semiconductor device shown in FIG. 1;

FIG. 6 is a diagram schematically showing a cross-sectional view of the main part in another process of manufacturing the semiconductor device shown in FIG. 1;

FIG. 7 is a diagram schematically showing a cross-sectional view of the main part in another process of manufacturing the semiconductor device shown in FIG. 1;

FIG. 8 is a diagram schematically showing a cross-sectional view of the main part in another process of manufacturing the semiconductor device shown in FIG. 1;

FIG. 9 is a diagram schematically showing a cross-sectional view of the main part in another process of manufacturing the semiconductor device shown in FIG. 1;

FIG. 10 is a diagram schematically showing a cross-sectional view of the main part in another process of manufacturing the semiconductor device shown in FIG. 1; and

FIG. 11 is a diagram schematically showing a cross-sectional view of a main part of a semiconductor device according to a modification.

### DETAILED DESCRIPTION

Next, a relevant technology is described only for understanding the following embodiments. A semiconductor device according to the relevant technology includes a plurality of p-type guard rings and a plurality of p-type diffusion regions in a termination region of a semiconductor layer. Each of the plurality of guard rings is disposed at a position exposed on a surface of the semiconductor layer. Each of the plurality of diffusion regions is disposed at a position deeper than a depth at which the plurality of guard rings is disposed. As described above, the plurality of guard rings and the plurality of diffusion regions are provided at different depths in the termination region of the semiconductor layer.

When the semiconductor device is turned off, a depletion layer spreads from an element region to the termination region. The depletion layer extends toward an outer peripheral side and a deep side of the termination region via the guard rings and the diffusion regions. Due to the guard rings and the diffusion regions, the depletion layer spreading from the element region greatly spreads toward the outer peripheral side and the deep side of the termination region, and a breakdown voltage of the semiconductor device can be improved.

In this type of semiconductor device, in order to obtain a high breakdown voltage, it is desirable that a relative positional relationship between the plurality of guard rings and the plurality of diffusion regions is appropriately arranged. However, as a result of studies by the present inventors, it has been found that it is difficult to appropriately arrange the relative positional relationship between the plurality of guard rings and the plurality of diffusion regions due to mask misalignment between a mask for forming the plurality of guard rings and a mask for forming the plurality of diffusion regions.

A semiconductor device according to an aspect of the present disclosure includes a semiconductor layer having an element region in which an element structure is disposed and a termination region located around the element region. The termination region includes a first breakdown voltage holding structure disposed in a first depth range of the semiconductor layer, and a second breakdown voltage holding structure disposed in a second depth range different from the first depth range of the semiconductor layer and arranged so as to face the first breakdown voltage holding structure in a depth direction of the semiconductor layer. At least one of the first breakdown voltage holding structure or the second breakdown voltage holding structure includes a RESURF layer. An electric field intensity distribution of the first breakdown voltage holding structure and an electric field intensity distribution of the second breakdown voltage holding structure have an opposite relationship of height from an inner peripheral side toward an outer peripheral side of the termination region.

In the semiconductor device, since at least one of the first breakdown voltage holding structure and the second breakdown voltage holding structure is configured by the RESURF layer, the influence of the deviation of the relative positional relationship between the first breakdown voltage holding structure and the second breakdown voltage holding structure can be restricted. Furthermore, in the semiconductor device, since the relationship between the height of the electric field intensity distribution of the first breakdown voltage holding structure and the height of the electric field intensity distribution of the second breakdown voltage holding structure is opposite, the electric field intensity distribution obtained by combining the electric field intensity distributions is made uniform from the inner peripheral side toward the outer peripheral side of the termination region. Therefore, the semiconductor device can hold a high voltage in the termination region of the semiconductor layer. As described above, the semiconductor device can have characteristics of allowing manufacturing variations and have high breakdown voltage characteristics.

A manufacturing method of a semiconductor device according to another aspect of the present disclosure includes: forming a mask on a semiconductor layer, the mask having an opening ratio that changes along at least one direction parallel to an upper surface of the semiconductor layer; reflowing the mask to change a thickness of the mask along the at least one direction; and implanting impurity ions into the semiconductor layer through the mask after the reflowing to form a RESURF layer.

According to the above-described manufacturing method, the RESURF layer having a changing impurity concentration can be formed by implanting impurity ions through the mask having the changing thickness. This manufacturing method is particularly useful when the material of the semiconductor layer is a material having small impurity diffusion.

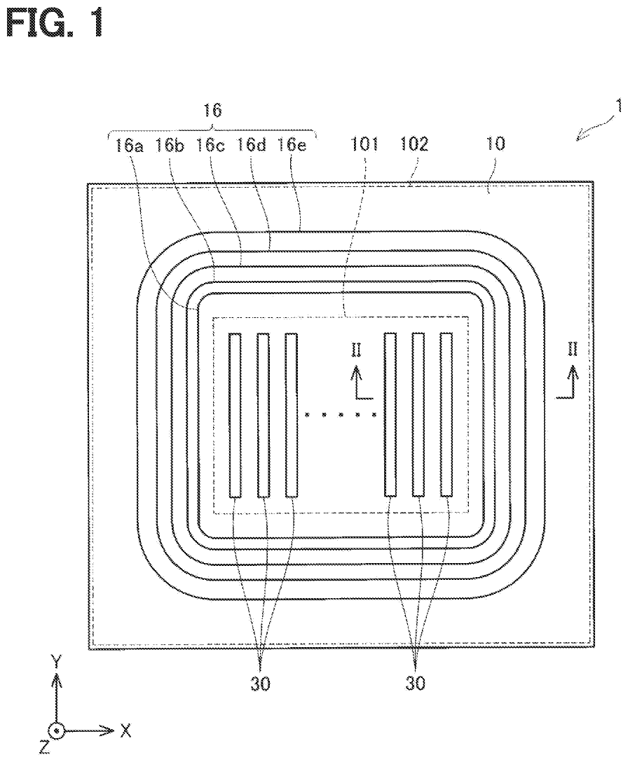

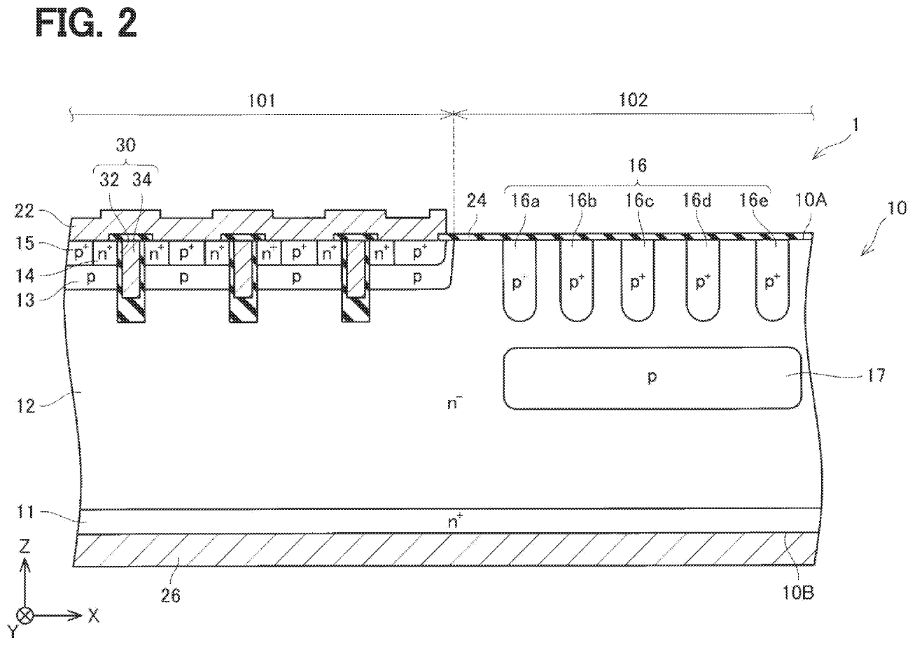

A semiconductor device 1 according to an embodiment of the present disclosure with be described with reference to FIG. 1 and FIG. 2. The semiconductor device 1 includes a semiconductor layer 10, a source electrode 22 covering a part of an upper surface 10A of the semiconductor layer 10, an interlayer insulating film 24 covering a part of the upper surface 10A of the semiconductor layer 10, a drain electrode 26 covering an entire surface of a lower surface 10B of the semiconductor layer 10, and a plurality of trench-type insulated gates 30. The semiconductor device 1 of the present embodiment is a vertical metal-oxide semiconductor field-effect transistor (MOSFET) and is adopted as a power semiconductor device. As shown in FIG. 2, the source electrode 22 and the interlayer insulating film 24 are disposed on the upper surface 10A of the semiconductor layer 10. However, these components are omitted in FIG. 1.

The semiconductor layer 10 is not particularly limited, but is, for example, a semiconductor layer made of silicon carbide (SiC). The semiconductor layer 10 includes an element region 101 and a termination region 102. As shown in FIG. 1, the element region 101 is disposed in the central portion of the semiconductor layer 10 when viewed from a direction (Z direction) orthogonal to the upper surface 10A of the semiconductor layer 10 (hereinafter, referred to as “in the plan view of the semiconductor layer 10”), and is defined in the semiconductor layer 10 as a range in which a switching element structure (in this example, a MOSFET structure) is formed. The termination region 102 is disposed in a peripheral portion of the semiconductor layer 10 and around the element region 101 in the plan view of the semiconductor layer 10, and is defined in the semiconductor layer 10 as a range in which a breakdown voltage holding structure is formed.

As shown in FIG. 2, the semiconductor layer 10 includes an n⁺-type drain region 11, an n⁻-type drift region 12, a p-type body region 13, a plurality of n⁺-type source regions 14, a plurality of p⁺-type body contact regions 15, a plurality of n⁺-type guard rings 16, and a p-type reduced surface field (RESURF) layer 17. In the present embodiment, the guard rings 16 include five guard rings 16a, 16b, 16c, 16d, and 16e. However, the number of guard rings is not limited to five and may be a different number. The guard rings 16 are also referred to as field limiting rings (FLRs). The body region 13, the source regions 14, and the body contact regions 15 are selectively formed in a surface layer portion in the element region 101. The guard rings 16 and the RESURF layer 17 are selectively formed in the termination region 102. In the present embodiment, a boundary between the element region 101 and the termination region 102 is defined by a peripheral edge of the body region 13.

The drain region 11 is disposed at a rear layer portion of the semiconductor layer 10 in both the element region 101 and the termination region 102, and is disposed at a position exposed on the lower surface 10B of the semiconductor layer 10. The drain region 11 contains n-type impurities (for example, nitrogen, phosphorus, or the like) at a high concentration, and is in ohmic contact with the drain electrode 26 covering the lower surface 10B of the semiconductor layer 10.

The drift region 12 is disposed on the drain region 11 in both the element region 101 and the termination region 102. An n-type impurity concentration of the drift region 12 is lower than an n-type impurity concentration of the drain region 11.

The body region 13 is disposed on the drift region 12 located in the element region 101, and is disposed in the surface layer portion of the semiconductor layer 10. The body region 13 is formed by introducing p-type impurities (for example, aluminum, boron, or the like) into the surface layer portion of the semiconductor layer 10 by using an ion implantation technique.

The source regions 14 are disposed on the body region 13 located in the element region 101, and are disposed at positions exposed on the upper surface 10A of the semiconductor layer 10. The source regions 14 are separated from the drift region 12 by the body region 13. The source regions 14 are formed by introducing n-type impurities into the surface layer portion of the semiconductor layer 10 using an ion implantation technique. The source regions 14 contain the n-type impurities at a high concentration and are in ohmic contact with the source electrode 22 covering the upper surface 10A of the semiconductor layer 10.

The body contact regions 15 are disposed on the body region 13 located in the element region 101, and are disposed at positions exposed on the upper surface 10A of the semiconductor layer 10. The body contact regions 15 are formed by introducing p-type impurities into the surface layer portion of the semiconductor layer 10 using an ion implantation technique. The body contact regions 15 contain a high concentration of the p-type impurities and are in ohmic contact with the source electrode 22 covering the upper surface 10A of the semiconductor layer 10.

As shown in FIG. 1, on the upper surface 10A of the semiconductor layer 10 in the range corresponding to the element region 101, the trench-type insulated gates 30 are arranged in a stripe manner in the plan view of the semiconductor layer 10. Each of the trench-type insulated gates 30 extends along one direction (Y direction). As shown in FIG. 2, each of the trench-type insulated gates 30 has a gate insulating film 32 made of silicon oxide and a gate electrode 34 made of polysilicon. The gate electrode 34 faces a portion of the body region 13 separating the drift region 12 and the source region 14 via the gate insulating film 32. As a result, the portion of the body region 13 separating the drift region 12 and the source region 14 can function as a channel region.

As described above, in the element region 101 of the semiconductor layer 10, a MOSFET structure including the drain region 11, the drift region 12, the body region 13, the source regions 14, the body contact regions 15, and the trench-type insulated gates 30 is formed. On the other hand, in the termination region 102 of the semiconductor layer 10, two breakdown voltage holding structures, that is, a breakdown voltage holding structure including the guard rings 16 and a breakdown voltage holding structure including the RESURF layer 17 are formed.

The guard rings 16 are disposed on the drift region 12 located in the termination region 102, and are disposed at positions exposed on the upper surface 10A of the semiconductor layer 10. The guard rings 16 are disposed in a range from the upper surface 10A of the semiconductor layer 10 to a predetermined depth. The potential of each of the guard rings 16 is floating. As shown in FIG. 1, each of the guard rings 16 is disposed so as to make a loop around the element region 101 in the plan view of the semiconductor layer 10, and has a similar shape concentric with the other guard rings. In this way, the guard rings 16 are laid out so that the individual guard rings repeatedly appear from the inner peripheral side to the outer peripheral side of the termination region 102.

As shown in FIG. 2, in the guard rings 16, the interval between adjacent guard rings is adjusted to increase from the inner peripheral side toward the outer peripheral side of the termination region 102. That is, in the plan view of the semiconductor layer 10, an area ratio of the guard rings 16 decreases from the inner peripheral side toward the outer peripheral side of the termination region 102. The area ratio of the guard rings 16 indicates an area of the guard rings 16 per unit area of the termination region 102.

The RESURF layer 17 is disposed in the drift region 12 located in the termination region 102, and is disposed in a predetermined depth range of the semiconductor layer 10. The RESURF layer 17 is a p-type diffusion region that continuously spreads in a plane direction of the semiconductor layer 10 from the inner peripheral side toward the outer peripheral side of the termination region 102. The potential of the RESURF layer 17 is floating. The RESURF layer 17 is separated from the guard rings 16, and is disposed so as to face the guard rings 16 in the depth direction of the semiconductor layer 10. Similarly to the guard rings 16, the RESURF layer 17 is disposed so as to make a loop around the element region 101 in the plan view of the semiconductor layer 10. As described in the manufacturing method described later, the RESURF layer 17 has a profile in which a p-type impurity concentration decreases from the inner peripheral side toward the outer peripheral side of the termination region 102.

Next, the operation of the semiconductor device 1 will be described. During the operation of the semiconductor device 1, a voltage at which the potential of the drain electrode 26 becomes higher than the potential of the source electrode 22 is applied between a drain and a source. When the potential of the gate electrode 34 becomes higher than a threshold value, a channel is formed in the body region 13 in a range in contact with the gate insulating film 32. Then, electrons flow from the source electrode 22 to the drain electrode 26 via the source regions 14, the channel, the drift region 12, and the drain region 11. On the other hand, when the potential of the gate electrode 34 becomes equal to or lower than the threshold value, the channel disappears and the flow of electrons stops. In this way, in the semiconductor device 1, the current flowing between the source electrode 22 and the drain electrode 26 can be controlled based on the potential of the gate electrode 34.

When the semiconductor device 1 is turned off, a depletion layer spreads in the drift region 12 from a pn junction surface of the drift region 12 and the body region 13. In the drift region 12 in the element region 101, the depletion layer spreads in a direction from the upper surface 10A toward the lower surface 10B. In the drift region 12 in the termination region 102, the depletion layer spreads in a direction from the inner peripheral side to the outer peripheral side. In the semiconductor device 1, since the two breakdown voltage holding structures including the guard rings 16 and the RESURF layer 17 are disposed in the termination region 102, the breakdown voltage holding structures are disposed up to a deep position of the termination region 102. Therefore, the depletion layer spreading from the element region 101 can largely spread toward the outer peripheral side and the deep side of the termination region 102.

In the semiconductor device 1, at least one of the two breakdown voltage holding structures is the RESURF layer 17. Therefore, even if the positional relationship between the guard rings 16 and the RESURF layer 17 deviates, the breakdown voltage does not significantly decrease. The semiconductor device 1 can tolerate manufacturing variations when forming the guard rings 16 and the RESURF layer 17.

Furthermore, in the semiconductor device 1, the area ratio (area per unit area) of the guard rings 16 in the plan view of the semiconductor layer 10 decreases from the inner peripheral side toward the outer peripheral side of the termination region 102. Therefore, the electric field intensity distribution of the guard rings 16 when the semiconductor device 1 is turned off is relatively low on the inner peripheral side of the termination region 102 and relatively high on the outer peripheral side of the termination region 102. That is, the electric field intensity distribution of the guard rings 16 tends to increase from the inner peripheral side toward the outer peripheral side of the termination region 102. On the other hand, in the semiconductor device 1, the p-type impurity concentration of the RESURF layer 17 decreases from the inner peripheral side toward the outer peripheral side of the termination region 102. Therefore, the electric field intensity distribution of the RESURF layer 17 when the semiconductor device 1 is turned off is relatively high on the inner peripheral side of the termination region 102 and relatively low on the outer peripheral side of the termination region 102. That is, the electric field intensity distribution of the RESURF layer 17 tends to decrease from the inner peripheral side toward the outer peripheral side of the termination region 102. As described above, in the semiconductor device 1, since the relationship between the height of the electric field intensity distribution of the guard rings 16 and the height of the electric field intensity distribution the RESURF layer 17 is opposite, the electric field intensity distribution obtained by combining the electric field intensity distributions is made uniform from the inner peripheral side toward the outer peripheral side of the termination region 102. Therefore, the semiconductor device 1 can hold a high voltage in the termination region 102, and the semiconductor device 1 can have high breakdown voltage characteristics.

Next, a manufacturing method of the semiconductor device 1 will be described. Since the manufacturing method of the semiconductor device 1 is characterized by a process of forming the RESURF layer 17, the process of forming the RESURF layer 17 will be described below, and the description of the other processes will be omitted.

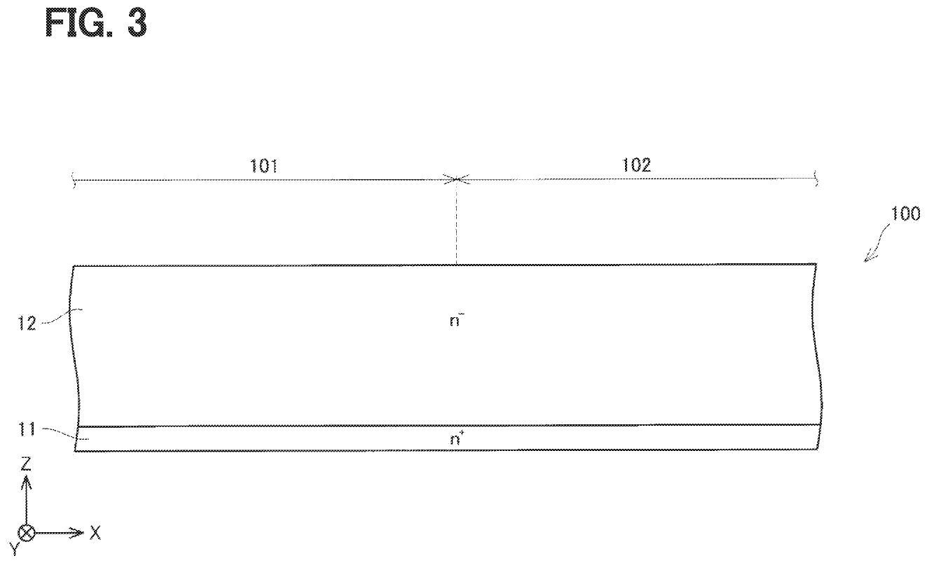

First, as shown in FIG. 3, a semiconductor layer 100 in which an epitaxial layer of silicon carbide is laminated on a silicon carbide substrate is prepared. The silicon carbide substrate is the drain region 11, and the epitaxial layer is a part of the drift region 12. As will be described later, a silicon carbide re-epitaxial layer is formed on the semiconductor layer 100 by an epitaxial growth technique to form the semiconductor layer 10 shown in FIG. 1 and FIG. 2.

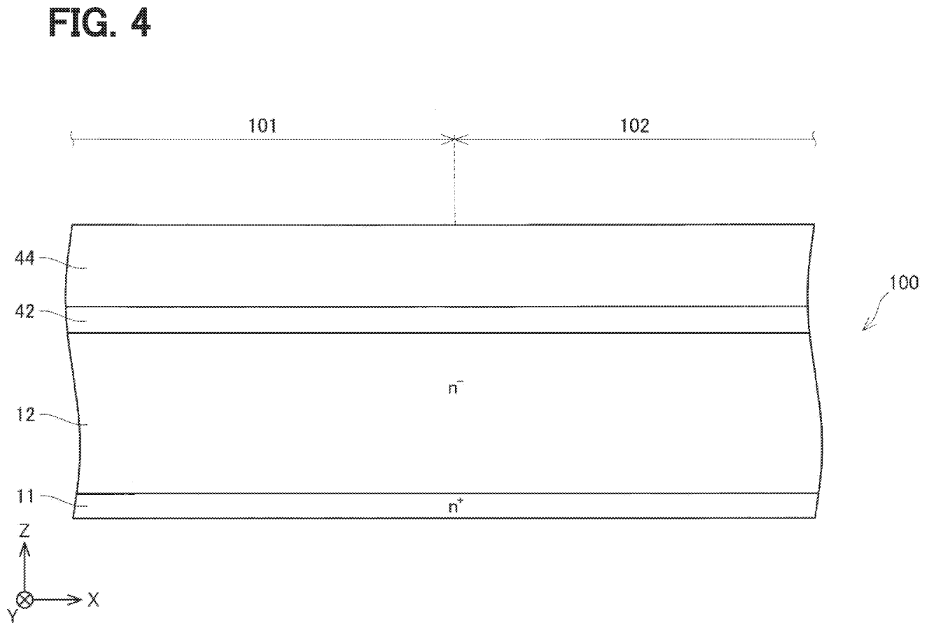

Next, as shown in FIG. 4, a non-doped silicate glass (NSG) film 42 and a boron-phosphorus silicate glass (BPSG) film 44 are formed above the semiconductor layer 100. The NSG film 42 is used to restrict diffusion of boron and phosphorus impurities contained in the BPSG film 44 into the semiconductor layer 100. As will be described later, the BPSG film 44 is used as a mask during ion implantation.

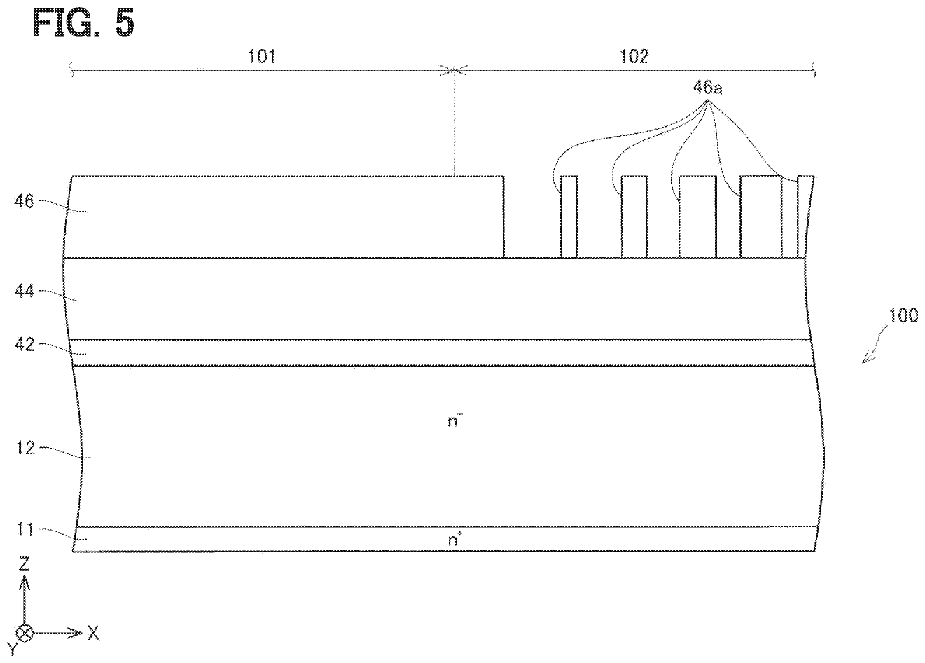

Next, as shown in FIG. 5, a resist 46 is formed on the BPSG film 44. In the resist 46, a plurality of openings 46a is formed in a range corresponding to the termination region 102. The resist 46 is formed such that an opening ratio decreases from the inner peripheral side toward the outer peripheral side of the termination region 102.

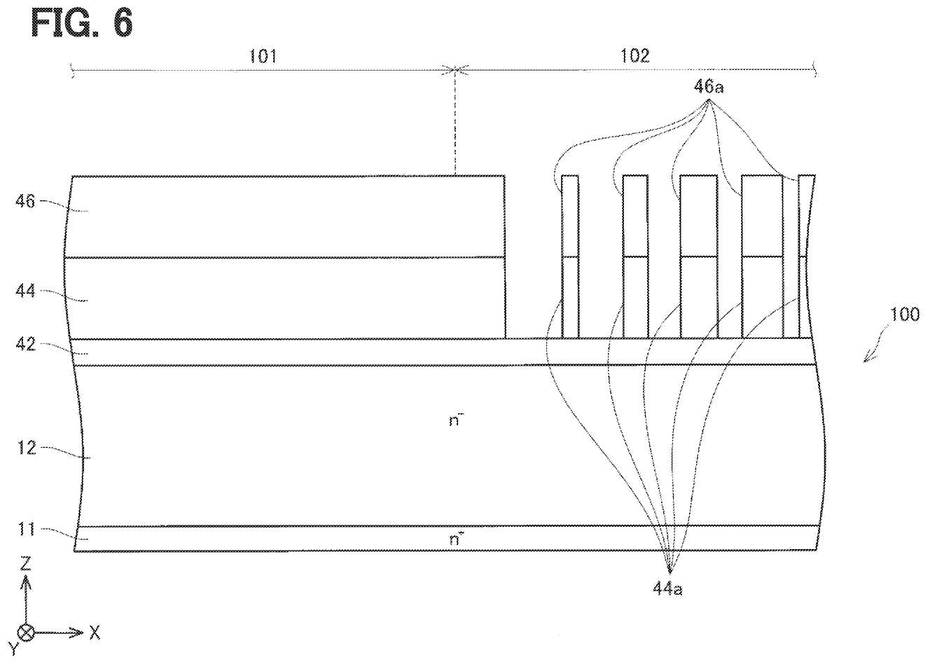

Next, as shown in FIG. 6, a part of the BPSG film 44 exposed from each of the openings 46a of the resist 46 is etched using a dry etching technique. As a result, a plurality of openings 44a corresponding to the plurality of openings 46a of the resist 46 is formed in the BPSG film 44.

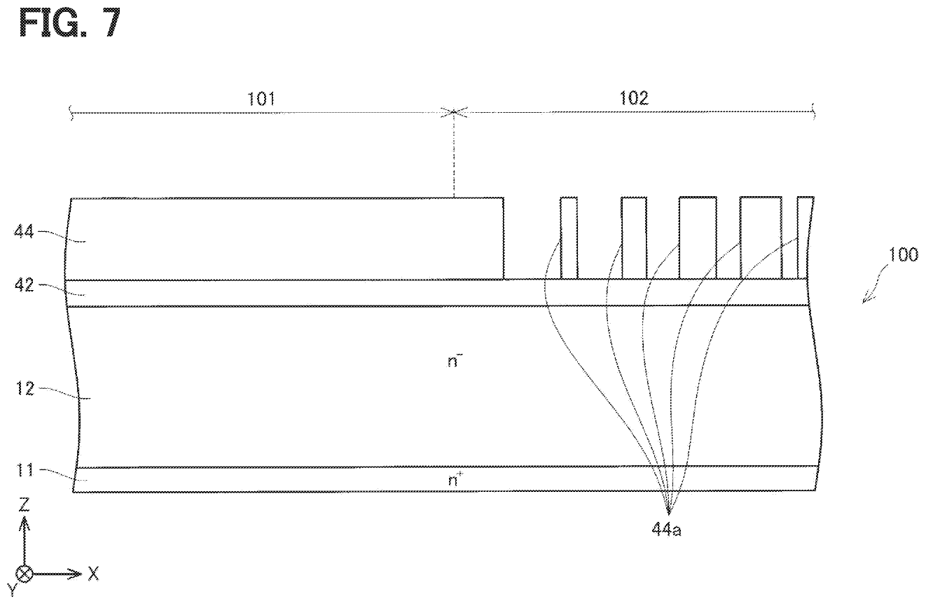

Next, as shown in FIG. 7, the resist 46 is removed using a resist stripping solution.

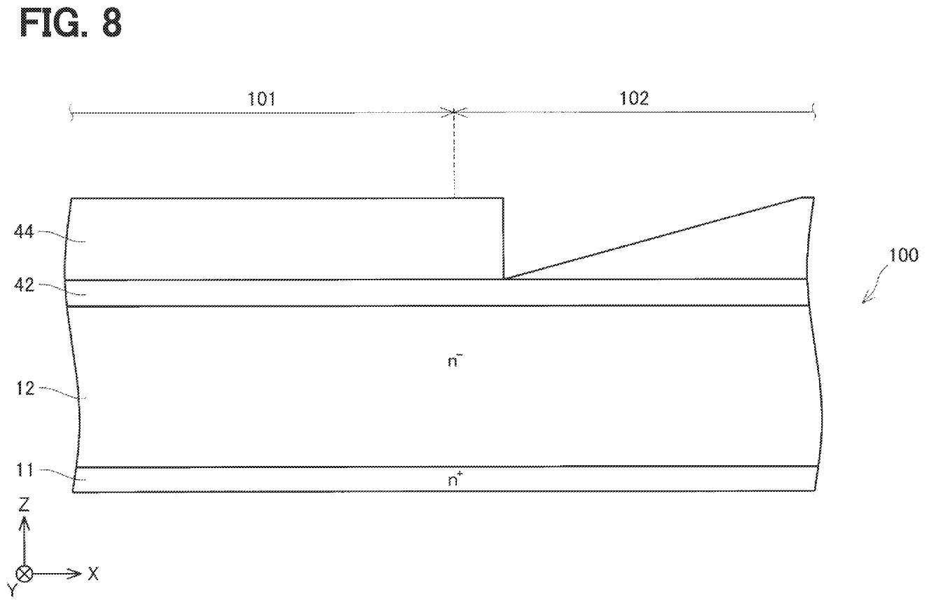

Next, as shown in FIG. 8, a surface of the BPSG film 44 is fluidized using a reflow technique. As a result, the surface of the BPSG film 44 is flattened in a tapered shape according to the opening ratio. Since the BPSG film 44 is formed such that the opening ratio of the BPSG film 44 decreases from the inner peripheral side toward the outer peripheral side of the termination region 102, the height of the surface of the BPSG film 44 increases from the inner peripheral side to the outer peripheral side of the termination region 102, that is, the thickness of the BPSG film 44 increases from the inner peripheral side toward the outer peripheral side of the termination region 102.

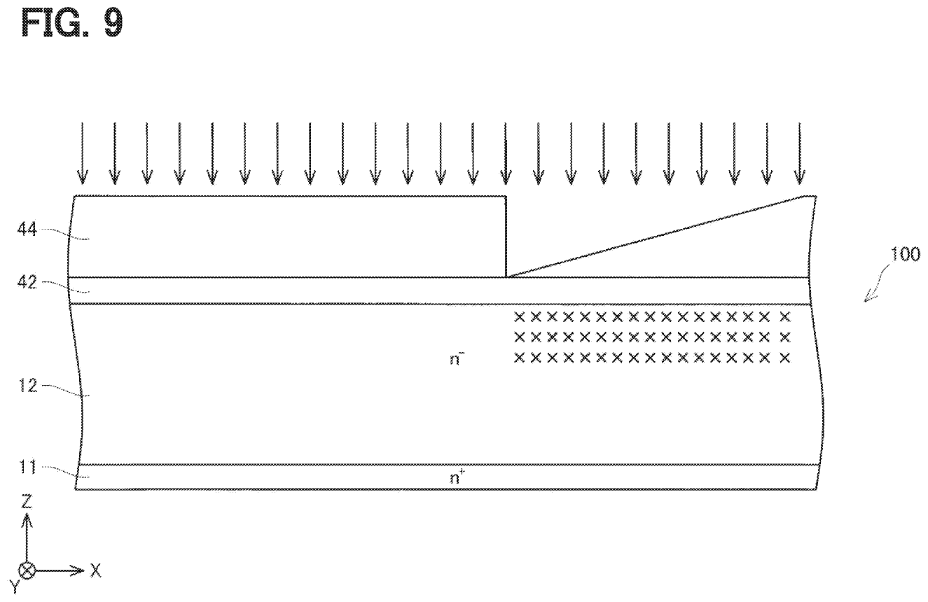

Next, as shown in FIG. 9, p-type impurities are implanted into the semiconductor layer 10 through the NSG film 42 and the BPSG film 44 by using an ion implantation technique. The p-type impurities are implanted into the semiconductor layer 10 while changing the implantation energy (that is, the implantation depth) of the p-type impurities. Since the thickness of the BPSG film 44 increases from the inner peripheral side toward the outer peripheral side of the termination region 102, the concentration of the p-type impurities introduced into the semiconductor layer 100 decreases from the inner peripheral side toward the outer peripheral side of the termination region 102.

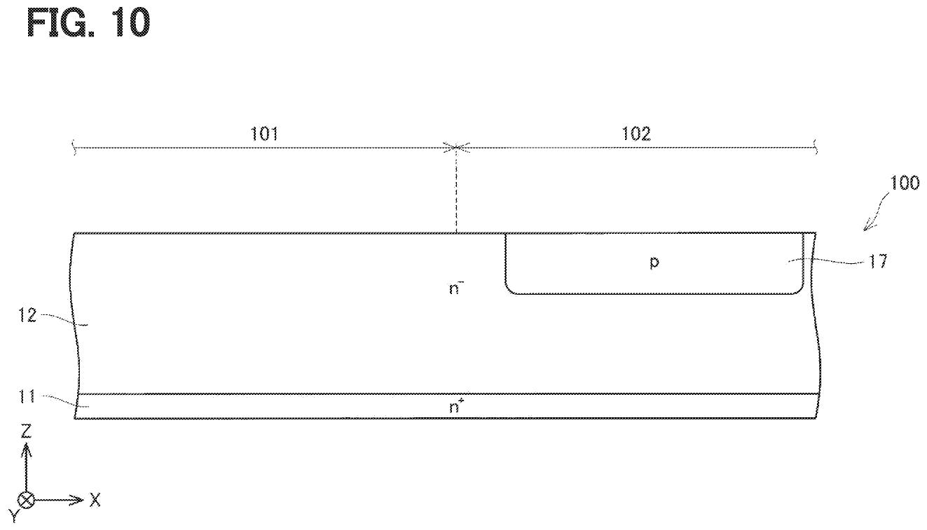

Next, as shown in FIG. 10, the implanted p-type impurities are activated by an annealing technique to form the RESURF layer 17. As a result, the RESURF layer 17 in which the p-type impurity concentration decreases from the inner peripheral side toward the outer peripheral side of the termination region 102 is formed. This annealing process may also be used as another annealing process.

Thereafter, a re-epitaxial layer corresponding to the remaining portion of the n⁻-type drift region 12 is formed on the semiconductor layer 100 by using an epitaxial growth technique. Furthermore, the surface structure of the element region 101 and the guard rings 16 of the termination region 102 are formed to complete the semiconductor device 1.

As is well known, in a semiconductor layer made of silicon carbide, a dopant hardly diffuses. For this reason, even when ion implantation is performed through a mask in which the opening ratio is changed, diffusion in the plane direction may be insufficient, and the RESURF layer may be intermittently formed in the plane direction, or the RESURF layer in which the impurity concentration repeats high and low in the plane direction may be formed. On the other hand, according to the above-described manufacturing method, prior to the ion implantation process, the BPSG film 44 whose thickness changes from the inner peripheral side to the outer peripheral side of the termination region 102 is formed, and ion implantation is performed through the BPSG film 44, whereby the RESURF layer 17 in which the impurity concentration in the plane direction continuously changes can be formed. As described above, the above-described method for forming the RESURF layer 17 is particularly useful when the material of the semiconductor layer is silicon carbide.

In the above-described embodiment, in the plan view of the semiconductor layer 10, the area ratio (area per unit area) of the guard rings 16 decreases from the inner peripheral side toward the outer peripheral side of the termination region 102, and the p-type impurity concentration of the RESURF layer 17 decreases from the inner peripheral side toward the outer peripheral side of the termination region 102. Instead of this example, in the plan view of the semiconductor layer 10, the area ratio (area per unit area) of the guard rings 16 may be increased from the inner peripheral side toward the outer peripheral side of the termination region 102, and the p-type impurity concentration of the RESURF layer 17 may be increased from the inner peripheral side toward the outer peripheral side of the termination region 102. Also in this case, similarly to the above-described embodiment, the relationship between the height of the electric field intensity distribution of the guard rings 16 and the height of the electric field intensity distribution of the RESURF layer 17 is opposite, and the semiconductor device 1 can have high breakdown voltage characteristics. The area ratio of the guard rings 16 may be adjusted by the interval between adjacent guard rings 16, may be adjusted by the area of each guard ring 16, or may be adjusted by combining them. In the above-described embodiment, the guard rings 16 are arranged in the shallow range of the semiconductor layer 10, and the RESURF layer 17 is arranged in the deep range of the semiconductor layer 10. Instead of this example, the guard rings 16 may be arranged in a deep range of the semiconductor layer 10, and the RESURF layer 17 may be arranged in a shallow range of the semiconductor layer 10. Also in this case, the area ratio of the guard rings 16 arranged in the deep range may increase from the inner peripheral side toward the outer peripheral side of the termination region 102, and the p-type impurity concentration of the RESURF layer 17 arranged in the shallow range may increase from the inner peripheral side toward the outer peripheral side of the termination region 102.

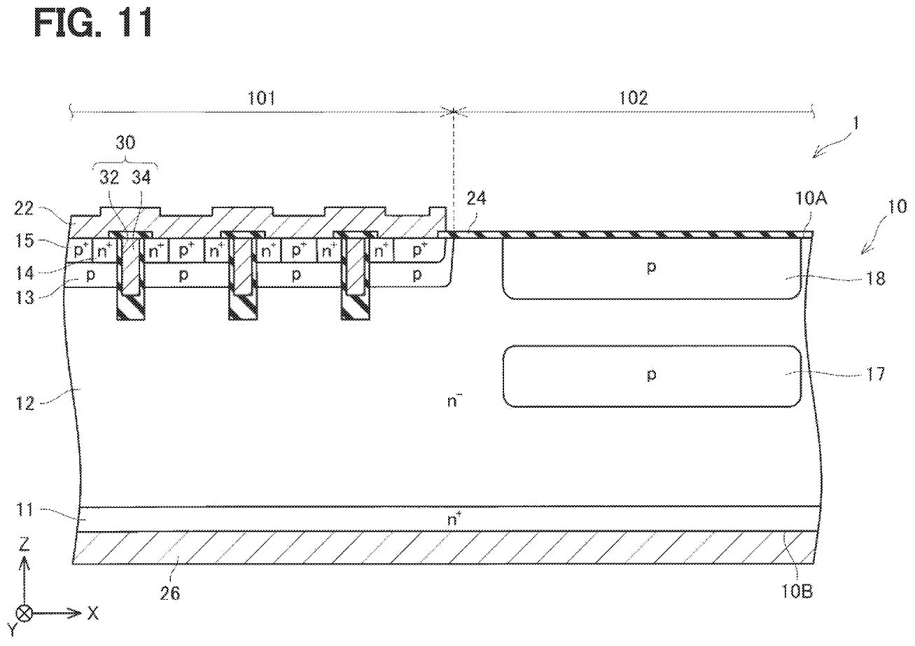

As illustrated in FIG. 11, two RESURF layers 17 and 18 may be disposed in the termination region 102. In this example, when a p-type impurity concentration of the RESURF layer 17 arranged in a deep range decreases from the inner peripheral side toward the outer peripheral side of the termination region 102, a p-type impurity concentration of the RESURF layer 18 arranged in the shallow range increases from the inner peripheral side toward the outer peripheral side of the termination region 102. Conversely, when the p-type impurity concentration of the RESURF layer 17 arranged in the deep range increases from the inner peripheral side toward the outer peripheral side of the termination region 102, the p-type impurity concentration of the RESURF layer 18 arranged in the shallow range decreases from the inner peripheral side toward the outer peripheral side of the termination region 102. In these cases, similarly to the above-described embodiment, the relationship between the heights of the electric field intensity distributions of the two RESURF layers 17 and 18 is opposite, and the semiconductor device 1 can have high breakdown voltage characteristics. The RESURF layers 17 and 18 can be formed using the above-described manufacturing method.

The technical elements disclosed herein are listed below. The following technical elements are useful independently.

A semiconductor device disclosed in the present specification may include a semiconductor layer having an element region in which an element structure is disposed and a termination region located around the element region. The material of the semiconductor layer is not particularly limited, but may be, for example, silicon carbide. As the element structure formed in the element region, various types of elements can be adopted. Examples of the element structure include a MOSFET structure and an insulated-gate bipolar transistor (IGBT) structure. The termination region may include a first breakdown voltage holding structure disposed in a first depth range of the semiconductor layer, and a second breakdown voltage holding structure disposed in a second depth range different from the first depth range of the semiconductor layer and disposed to face the first breakdown voltage holding structure in a depth direction of the semiconductor layer. The first depth range may be a range shallower than the second depth range, and the first depth range may be a range deeper than the second depth range. At least one of the first breakdown voltage holding structure or the second breakdown voltage holding structure includes a RESURF layer. An electric field intensity distribution of the first breakdown voltage holding structure and an electric field intensity distribution of the second breakdown voltage holding structure have an opposite relationship of height from an inner peripheral side to an outer peripheral side of the termination region.

In the semiconductor device, the first breakdown voltage holding structure may include the RESURF layer, and the second breakdown voltage holding structure may include a plurality of guard rings. In this case, (i) in a case where an impurity concentration of the RESURF layer of the first breakdown voltage holding structure decreases from the inner peripheral side toward the outer peripheral side, an area ratio of the guard rings of the second breakdown voltage holding structure decreases from the inner peripheral side toward the outer peripheral side, and (ii) in a case where the impurity concentration of the RESURF layer of the first breakdown voltage holding structure increases from the inner peripheral side toward the outer peripheral side, the area ratio of the guard rings of the second breakdown voltage holding structure increases from the inner peripheral side toward the outer peripheral side. In either case of (i) and (ii), the relationship between the heights of the electric field intensity distributions of the first breakdown voltage holding structure and the level of the electric field intensity distribution of the second breakdown voltage holding structure is opposite, and the semiconductor device can have high breakdown voltage characteristics.

In the semiconductor device, the first breakdown voltage holding structure may include the RESURF layer, and the second breakdown voltage holding structure may include another RESURF layer. In this case, in a case where an impurity concentration of the RESURF layer of the first breakdown voltage holding structure decreases from the inner peripheral side toward the outer peripheral side, an impurity concentration of the RESURF layer of the second breakdown voltage holding structure may increase from the inner peripheral side toward the outer peripheral side. The relationship between the height of the electric field intensity distribution of the first breakdown voltage holding structure and the height of the electric field intensity distribution of the second breakdown voltage holding structure is opposite, and the semiconductor device can have high breakdown voltage characteristics.

A manufacturing method of a semiconductor device disclosed in the present specification may include: forming a mask on a semiconductor layer, the mask having an opening ratio that changes along at least one direction parallel to an upper surface of the semiconductor layer; reflowing the mask to change a thickness of the mask along the at least one direction; and implanting impurities ions into the semiconductor layer through the mask after the reflowing to form a RESURF layer. The material of the semiconductor layer is not particularly limited, but may be, for example, silicon carbide. The manufacturing method can form any of the RESURF layers required in various regions.

In the manufacturing method, the semiconductor layer may include an element region in which an element structure is formed and a termination region located around the element region. In the forming of the mask, the mask is formed to have the opening ratio that changes from an inner peripheral side toward an outer peripheral side in the termination region. According to this manufacturing method, the RESURF layer can be formed in the termination region.

Although the embodiments have been described in detail above, these are merely examples and do not limit the scope of claims. The techniques described in the claims include various modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve a plurality of objectives at the same time, and achieving one of the objectives itself has technical usefulness.

What is claimed is:

1. A semiconductor device comprising
a semiconductor layer having an element region in which an element structure is disposed and a termination region located around the element region, wherein
the termination region includes:
a first breakdown voltage holding structure disposed in a first depth range of the semiconductor layer; and
a second breakdown voltage holding structure disposed in a second depth range different from the first depth range of the semiconductor layer and arranged so as to face the first breakdown voltage holding structure in a depth direction of the semiconductor layer,
at least one of the first breakdown voltage holding structure or the second breakdown voltage holding structure includes a reduced surface filed (RESURF) layer, and
an electric field intensity distribution of the first breakdown voltage holding structure and an electric field intensity distribution of the second breakdown voltage holding structure have an opposite relationship of height from an inner peripheral side toward an outer peripheral side of the termination region.

2. The semiconductor device according to claim 1, wherein
the semiconductor layer is made of silicon carbide.

3. The semiconductor device according to claim 1, wherein
the first breakdown voltage holding structure includes the RESURF layer, the second breakdown voltage holding structure includes a plurality of guard rings,
an area of the plurality of guard rings per unit area of the termination region is defined as an area ratio of the plurality of guard rings, and
(i) an impurity concentration of the RESURF layer of the first breakdown voltage holding structure decreases from the inner peripheral side toward the outer peripheral side, and the area ratio of the plurality of guard rings of the second breakdown voltage holding structure decreases from the inner peripheral side toward the outer peripheral side, or
(ii) the impurity concentration of the RESURF layer of the first breakdown voltage holding structure increases from the inner peripheral side toward the outer peripheral side, and the area ratio of the plurality of guard rings of the second breakdown voltage holding structure increases from the inner peripheral side toward the outer peripheral side.

4. The semiconductor device according to claim 1, wherein
the first breakdown voltage holding structure includes the RESURF layer,
the second breakdown voltage holding structure includes another RESURF layer,
an impurity concentration of the RESURF layer of the first breakdown voltage holding structure decreases from the inner peripheral side toward the outer peripheral side, and
an impurity concentration of the RESURF layer of the second breakdown voltage holding structure increases from the inner peripheral side toward the outer peripheral side.

5. A manufacturing method of a semiconductor device, comprising:
forming a mask on a semiconductor layer, the mask having an opening ratio that changes along at least one direction parallel to an upper surface of the semiconductor layer;
reflowing the mask to change a thickness of the mask along the at least one direction; and
implanting impurity ions into the semiconductor layer through the mask after the reflowing to form a reduced surface field (RESURF) layer.

6. The manufacturing method according to claim 5, wherein
the semiconductor layer includes an element region in which an element structure is formed and a termination region located around the element region, and
in the forming of the mask, the mask is formed to have the opening ratio that changes from an inner peripheral side toward an outer peripheral side of the termination region.

7. The manufacturing method according to claim 5, wherein
the semiconductor layer is made of silicon carbide.
